(19) United States
(12) Patent Application Publication
(10) Pub. No.: US 2013/0077714 A1
(43) Pub. Date: Mar. 28, 2013

(54) APPARATUS AND METHOD FOR TRANSMITTING AND RECEIVING DATA

(71) Applicants: Jong Soo LIM, Daejeon (KR); Sun Hyoung KWON, Seoul (KR); ELECTRONICS AND TELECOMMUNICATIONS RESEARCH INSTITUTE, Daejeon (KR)

(72) Inventors: Jong Soo LIM, Daejeon (KR); Sun Hyoung KWON, Seoul (KR); ELECTRONICS AND TELECOMMUNICATIONS RESEARCH INSTITUTE, Daejeon (KR)

(73) Assignee: ELECTRONICS AND TELECOMMUNICATIONS RESEARCH INSTITUTE, Daejeon (KR)

(21) Appl. No.: 13/628,978

(22) Filed: Sep. 27, 2012

(30) Foreign Application Priority Data
Sep. 27, 2011 (KR) 10-2011-0097789
Aug. 14, 2012 (KR) 10-2012-0089115

(51) Int. Cl. H04L 27/12; H04L 27/14; H03D 1/04

(52) U.S. Cl. 375/302; 375/346; 375/324

(57) ABSTRACT

A data transmitting apparatus generates a plurality of modulation data symbols by performing symbol mapping of input data, converts and angle-modulates the plurality of modulation data symbols from a frequency domain to a real number signal of a time domain, and circular-shifts and transmits the angle-modulated signal from a signal of a frequency domain.

### CROSS-REFERENCE TO RELATED APPLICATION

This application claims priority to and the benefit of Korean Patent Application No. 10-2011-0097789 and 10-2012-0089115 filed in the Korean Intellectual Property Office on Sep. 27, 2011 and Aug. 14, 2012, the entire contents of which are incorporated herein by reference.

### BACKGROUND OF THE INVENTION

(a) Field of the Invention

The present invention relates to a method and apparatus for transmitting and receiving data. More particularly, the present invention relates to a method and apparatus for transmitting and receiving data using orthogonal frequency-division multiplexing (OFDM) modulation and angle modulation.

(b) Description of the Related Art

OFDM can be embodied through a simple equalizer, has a strong characteristic on multipath fading, and is thus selected and used for several wireless communication systems such as a wireless local area network (WLAN), a wireless metropolitan area network (WMAN), digital audio broadcasting (DAB), and digital video broadcasting (DVB).

However, an OFDM signal has a high peak-to-average power ratio (PAPR), and due to such a high PAPR, distortion by modulation between mutual frequencies of an OFDM signal occurs and resultantly system performance is deteriorated.

### SUMMARY OF THE INVENTION

The present invention has been made in an effort to provide a method and apparatus for transmitting and receiving data, having advantages of lowering a PAPR.

An exemplary embodiment of the present invention provides an apparatus that transmits data. The data transmitting apparatus includes an OFDM modulation unit, a PAPR controller, and a signal transmitting unit. The OFDM modulation unit generates a plurality of modulation data symbols by performing symbol mapping of input data, and converts the plurality of modulation data symbols from a signal of a frequency domain to a real number signal of a time domain. The PAPR controller angle-modulates the real number signal of a time domain and circular-shifts the angle-modulated signal from a signal of a frequency domain. The signal transmitting unit transmits the circular-shifted signal.

The OFDM modulation unit may include an input signal processor that generates a plurality of input signals using the plurality of modulation data symbols, and an inverse fast Fourier transform (IFFT) unit that generates a real number signal by performing IFFT of the plurality of input signals. The plurality of input signals may include the plurality of modulation data symbols and a plurality of conjugation symbols that are generated by conjugating the plurality of modulation data symbols.

The number of the plurality of modulation data symbols may be N/2, and when a magnitude of the IFFT is N, the input signal processor may correspond N/2 modulation data symbols to positions from 0 to an (N/2−1)th input signal, correspond a plurality of conjugation symbols of N/2 to positions from N/2 to an (N−1)th input signal, and position a conjugation symbol of an (N/2−k)th input signal at positions of input signals from N/2nd to N−1. The N may be a positive number, and k may be a value from N/2 to N−1.

The PAPR controller may include: a fast Fourier transform (FFT) unit that converts the angle-modulated signal from a signal of a time domain to a signal of a frequency domain; a shift unit that shifts the signal of a frequency domain by a predetermined circular shift value; and an IFFT unit that converts the circular-shifted signal from a signal of a frequency domain to a signal of a time domain and that outputs the converted signal to the signal transmitting unit.

The PAPR controller may include a scaling unit that adjusts a magnitude of the real number signal by multiplying an angle modulation index by a real number signal of the time domain.

Another embodiment of the present invention provides an apparatus that receives data. The data receiving apparatus include a signal receiving unit, a PAPR controller, and an OFDM demodulation unit. The signal receiving unit receives a signal from a data transmitting apparatus. The PAPR controller converts a received signal from a time domain to a signal of a frequency domain and circular-shifts the signal of a frequency domain in an opposite direction by a circular shift value of a data transmitting apparatus, and calculates a phase estimation value by angle demodulation. The OFDM demodulation unit converts the phase estimation value from a time domain to a signal of a frequency domain and restores data by symbol demapping.

The PAPR controller may include: an FFT unit that converts the receiving signal from a time domain to a signal of a frequency domain; a channel estimation unit that estimates a channel from a magnitude of a DC component that is shifted by a circular shift value in the data transmitting apparatus among signals of a frequency domain; and an equalizer that compensates the signal of a frequency domain using the estimated channel.

The PAPR controller may further include: an IFFT unit that converts the circular-shifted signal of a frequency domain to a signal of a time domain; and an angle demodulation unit that calculates a phase estimation value by performing inverse tangent of a value that divides an imaginary number value by a real number signal in the signal of a time domain.

The PAPR controller may further include a scaling unit that adjusts a magnitude of the phase estimation value by dividing the phase estimation value by an angle modulation index. The angle modulation index may be used for adjusting a magnitude of a signal in the data transmitting apparatus.

Yet another embodiment of the present invention provides a method of transmitting data in a data transmitting apparatus. The method includes: generating a plurality of modulation data symbols by performing symbol mapping of input data; converting the plurality of modulation data symbols from a frequency domain to a real number signal of a time domain; angle-modulating the real number signal of a time domain; circular-shifting the angle modulated-signal from a signal of a frequency domain; and transmitting the circular-shifted signal.

The circular-shifting of the angle modulated-signal may include converting the angle modulated-signal from a signal of a time domain to the signal of a frequency domain, and shifting an entire signal of a frequency domain by a predetermined circular shift value.

The converting of the plurality of modulation data symbols may include generating a plurality of input signals using the plurality of modulation data symbols, and generating the real number signal by performing IFFT of the plurality of input signals. The plurality of input signals may include the plurality of modulation data symbols and a plurality of conjugation symbols that are generated by conjugating the plurality of modulation data symbols.

Yet another embodiment of the present invention provides a method of receiving data in a data receiving apparatus. The method includes: converting a received signal from a time domain to a signal of a frequency domain; estimating a channel from a magnitude of a DC component that is shifted by a circular shift value in a data transmitting apparatus among the signals of a frequency domain; and compensating distortion of the signal of a frequency domain using the estimated channel.

The method may further include: calculating a phase estimation value by circular-shifting and angle-demodulating the signal of a frequency domain in which distortion is compensated in an opposite direction by the circular shift value; and restoring the data by symbol-demapping the phase estimation value in a signal of a frequency domain.

### BRIEF DESCRIPTION OF THE DRAWINGS

FIG. 1 is a diagram illustrating a constant envelope-orthogonal frequency division multiplexing (CE-OFDM) data transmitting apparatus according to an exemplary embodiment of the present invention.

FIG. 2 is a flowchart illustrating a method of transmitting data of a CE-OFDM data transmitting apparatus according to a first exemplary embodiment of the present invention.

FIG. 3 is a diagram illustrating an RSC that is shown in FIG. 1.

FIG. 4 is a graph illustrating a magnitude of an output signal of an FFT unit having no circular shift.

FIG. 5 is a graph illustrating a magnitude of an output signal of an FFT unit that is shifted to a 20th circular shift in a right direction.

FIG. 6A is a graph illustrating an output signal of an IFFT unit of a signal having no circular shift.

FIG. 6B is a graph illustrating a magnitude of an output signal of an IFFT unit of a signal having no circular shift.

FIG. 7A is a graph illustrating an output signal of an IFFT unit of a signal that is shifted to a 20th circular shift in a right direction.

FIG. 7B is a graph illustrating a magnitude of an output signal of an IFFT unit of a signal that is shifted to a 20th circular shift in a right direction.

FIG. 8 is a diagram illustrating a CE-OFDM data receiving apparatus according to an exemplary embodiment of the present invention.

FIG. 9 is a flowchart illustrating a method of receiving data of a CE-OFDM data receiving apparatus according to an exemplary embodiment of the present invention.

FIG. 10 is a graph illustrating an example of a signal of a frequency domain that is output from an FFT unit that is shown in FIG. 9.

FIG. 11 is a diagram illustrating an RSDC that is shown in FIG. 8.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In addition, in the entire specification and claims, unless explicitly described to the contrary, the word “comprise” and variations such as “comprises” or “comprising” will be understood to imply the inclusion of stated elements but not the exclusion of any other elements.

Hereinafter, a method and apparatus for transmitting and receiving data according to an exemplary embodiment of the present invention will be described in detail with reference to the drawings.

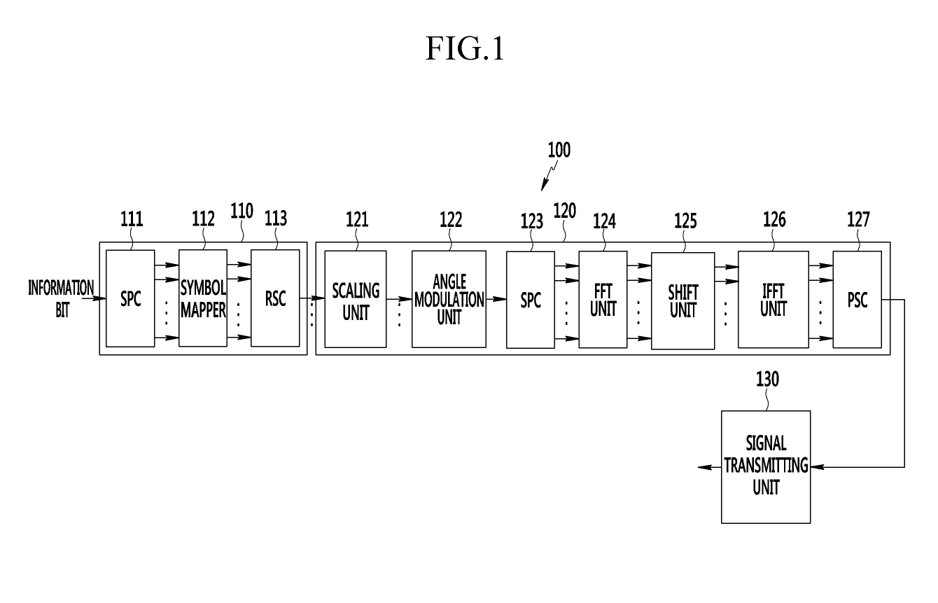

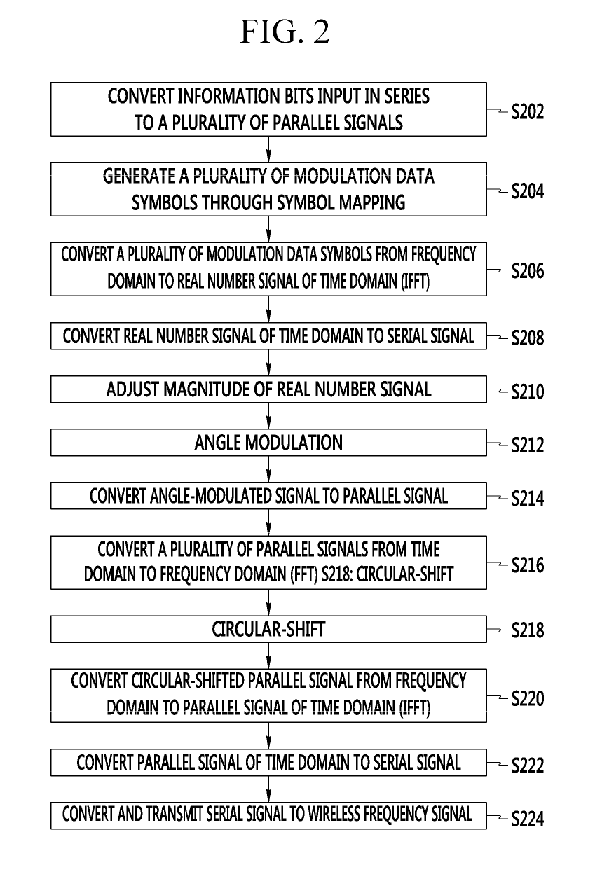

FIG. 1 is a diagram illustrating a CE-OFDM data transmitting apparatus according to an exemplary embodiment of the present invention, and FIG. 2 is a flowchart illustrating a method of transmitting data of a CE-OFDM data transmitting apparatus according to a first exemplary embodiment of the present invention.

Referring to FIG. 1, a CE-OFDM data transmitting apparatus 100 includes an OFDM modulation unit 110, a PAPR controller 120, and a signal transmitting unit 130.

The OFDM modulation unit 110 includes a serial to parallel converter (SPC) 111, a symbol mapper 112, and a real signal converter (RSC) 113.

The PAPR controller 120 includes a scaling unit 121, an angle modulation unit 122, an SPC 123, a fast Fourier transform (FFT) unit 124, a shift unit 125, an inverse fast Fourier transform (IFFT) unit 126, and a parallel to serial converter (PSC) 127.

Referring to FIG. 2, the SPC 111 converts information bits that are input in series to a plurality of parallel signals, and outputs the plurality of parallel signals to the symbol mapper (S202).

The symbol mapper 112 performs symbol mapping of a plurality of parallel signals that are output from the SPC 111 through digital modulation such as binary phase shift keying (BPSK), quadrature amplitude modulation (QAM), 16-QAM, and 64-QAM and thus generates a plurality of modulation data symbols (S204), and outputs the generated plurality of modulation data symbols to the RSC 113.

In order to perform angle modulation of a plurality of modulation data symbols in the angle modulation unit 122, the plurality of modulation data symbols should be converted to real number signals, and the RSC 113 performs such a function.

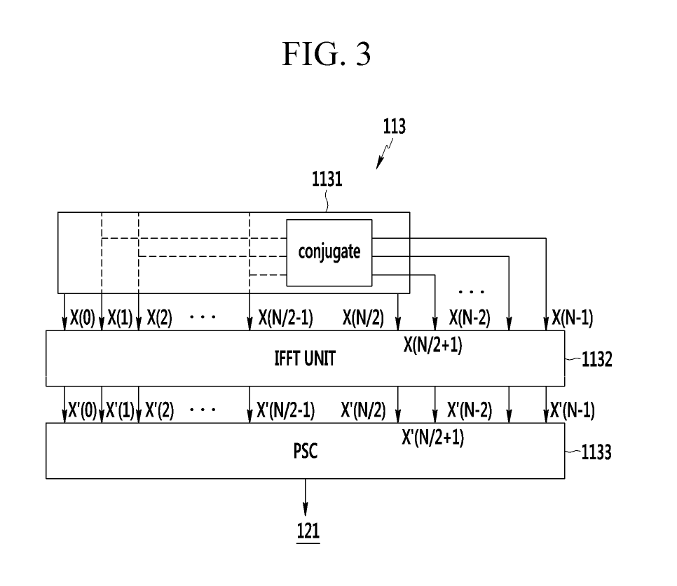

FIG. 3 is a diagram illustrating an RSC that is shown in FIG. 1.

Referring to FIG. 3, the RSC 113 includes an input signal processor 1131, an IFFT unit 1132, and a PSC 1133.

The input signal processor 1131 generates a plurality of input signals of the IFFT unit 1132 using a plurality of modulation data symbols.

When a magnitude of the IFFT unit 1132 is N, the number of modulation data symbols may be N/2. Here, N corresponds to a multiple of 2. Therefore, the input signal processor 1131 conjugates N/2 modulation data symbols, generates N/2 conjugation symbols, and outputs the N/2 modulation data symbols and the N/2 conjugation symbols to the IFFT unit 1132.

That is, input signals [X(0), X(1), . . . , X(N/2−1)] of the IFFT unit 1132 correspond to N/2 modulation data symbols that are output from the symbol mapper 112, and in input signals [X(N/2), X(N/2+1), . . . , X(2N−1)] of the IFFT unit 1132, N/2 modulation data symbols correspond to N/2 conjugation symbols. In this case, a 0th modulation data symbol is 0, and thus a modulation data symbol that is input to input signals [X(0), X(N/2)] becomes 0.

That is, modulation data symbols from 0th to {(N/2)−1}th modulation data symbols are used for the input signals [X(1), . . . , X(N/2−1)], and a modulation data symbol of an input signal [X(N−k)] is conjugated and used for input signals [X(N/2+1), . . . , X(N−1)]. Here, k is N/2+1, N/2+2, . . . , N−1. In this way, an output signal of the IFFT unit 1132 may become a real number signal.

The IFFT unit 1132 performs IFFT of input signals [X(0), X(1), . . . , X(N−1)]. Thereafter, modulation data symbols of a frequency domain are converted to real number signals [X′(0), X′(1), . . . , X′(N−1)] of a time domain.

The PSC 1133 converts the real number signals [X′(0), X′(1), . . . , X′(N−1)] from a parallel signal to a serial signal.

In this way, the RSC 113 converts a plurality of modulation data symbols from a frequency domain to a real number signal of a time domain (S206), converts the real number signal of a time domain to a serial signal (S208), and outputs the serial signal to the scaling unit 121.

For example, when a magnitude of the IFFT unit 1132 is 128, when a digital modulation method is 16 QAM, and when a plurality of modulation data symbols that are output from the symbol mapper 112 are 1+j, 3+3*j, −1−j, . . . , in order to enable an output of the IFFT unit 1132 to have only a real number value, 128 input signals that are generated by the input signal processor 1131 become [X(0)]=0, [X(1)]=1+j, [X(2)]=3+3*j, [X(3)]=−1−j, . . . , [X(64)]=0, . . . , [X(125)]=−1+j, [X(126)]=3−3j, [X(127)]=1−j.

In the input signal processor 1131, when a value that multiplies −1 by N/2 conjugation symbols is used for input signals [X(N/2+1), . . . , X(N−1)], an output signal of the IFFT unit 1132 is converted to an imaginary number signal of a time domain having only an imaginary number portion, and such an imaginary number signal may be output to the scaling unit 121.

The scaling unit 121 adjusts a magnitude of a real number signal by multiplying an angle modulation index m by a real number signal that is output from the PSC 1133 (S210), and outputs a signal having an adjusted magnitude to the angle modulation unit 122. For example, when a real number signal that is output from the PSC 1133 is defined as xₜ and xₜ=xₜ₁, xₜ₂, xₜ₃, . . . , xₜₙ, an angle modulation index m may be multiplied to xₜ so that xₜ is

$$\frac{- r}{2} \leq {x}_{t} \leq \frac{π}{2} .$$

Here, π is a circular constant.

The angle modulation unit 122 performs angle modulation of a signal that is output from the scaling unit 121 (S212). When an angle-modulated signal of a k-th real number signal by the angle modulation unit 122 is defined as θ(tk), θ(tk) is expressed by Equation 1.

θ(tk)=exp(j×xₜₖ)=cos(m×xₜₖ)+j×sin(m×xₜₖ) (Equation 1)

In general, a PAPR within one OFDM symbol is expressed by Equation 2. A guard interval is inserted into a serial signal of a time domain that is output from the RSC 113, and both a guard interval and a signal corresponding to one modulation data symbol are referred to as an OFDM symbol.

$$10 \times log \frac{{max}_{t ∈ [ 0 , T )} {\vert θ ( tk ) \vert}^{2}}{E \{ {\vert θ ( tk ) \vert}^{2} \}} \qquad ( Equation 2 )$$

Here, E{•} is an expected value, and T represents a cycle of one OFDM symbol.

In this case, |θ(tk)| is expressed by Equation 3.

|θ(tk)|=cos²(m×xₜₖ)+sin²(m×xₜₖ)=1 [Equation 3]

Therefore, a PAPR (dB) according to an exemplary embodiment of the present invention is expressed as 0 by Equation 4.

$$\begin{matrix}10 \times log \frac{{max}_{t ∈ [ 0 , T )} {\vert θ ( tk ) \vert}^{2}}{E \{ {\vert θ ( tk ) \vert}^{2} \}} = 10 \times log \frac{{max}_{t ∈ [ 0 , T )} {1}^{2}}{E \{ {1}^{2} \}} \\ = 10 \times log 1 \\ = 0 ( dB )\end{matrix} \qquad ( Equation 4 )$$

Next, the SPC 123 converts an angle-modulated signal from a serial signal to a parallel signal (S214) and outputs the converted signal to the FFT unit 124.

The FFT unit 124 performs FFT of a plurality of parallel signals that are output from the SPC 123, and converts a signal of a time domain to a signal of a frequency domain (S216) and outputs a plurality of parallel signals of a frequency domain to the shift unit 125.

The shift unit 125 circular-shifts a plurality of parallel signals that are output from the FFT unit 124 by a predetermined circular shift value in a right direction or a left direction (S218). The shift unit 125 outputs the circular-shifted parallel signal to the IFFT unit 126.

When a magnitude of the FFT unit 124 is 128, the shift unit 125 circular-shifts the signal by 0-127. Here, 0 corresponds to a case of having no circular shift. That is, a circular shift value may be set to one of 0 to 127 values.

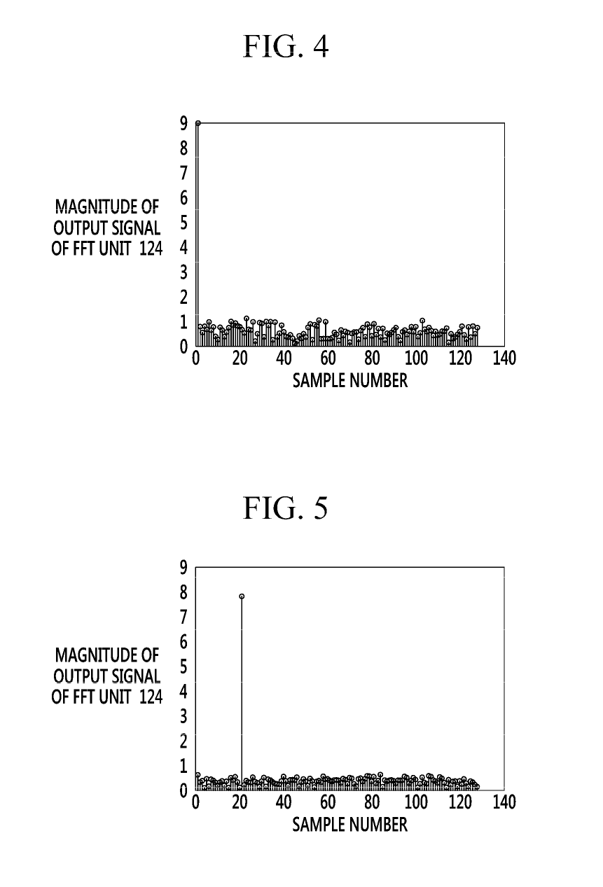

FIG. 4 is a graph illustrating a magnitude of an output signal of an FFT unit 124 having no circular shift, and FIG. 5 is a graph illustrating a magnitude of an output signal of an FFT unit 124 that is shifted to a 20th circular shift in a right direction.

As shown in FIG. 4, a plurality of parallel signals that are output from the FFT unit 124 have a characteristic in which energy is concentrated to a DC component (0th subcarrier position). When a plurality of parallel signals that are output from the FFT unit 124 are shifted to a 20th circular shift in a right direction, a DC component also moves, as shown FIG. 5.

In this way, by shifting a DC component in which energy is concentrated in a frequency domain, the DC component may be used for estimating a frequency channel and for adjusting time synchronization in a time domain. By using the DC component, an additional information signal for estimating a channel may not be periodically transmitted to a specific subcarrier position like a pilot.

The IFFT unit 126 performs IFFT of a circular-shifted signal that is output from the shift unit 125, thereby again converting a signal of a frequency domain to a signal of a time domain (S220).

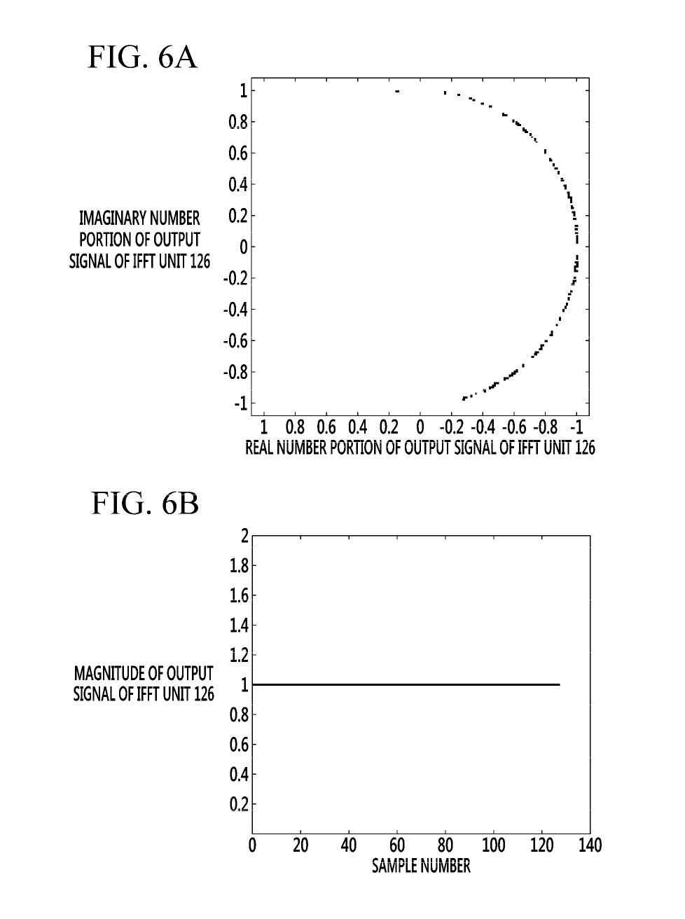

FIG. 6A is a graph illustrating an output signal of an IFFT unit 126 of a signal having no circular shift, and FIG. 6B is a graph illustrating a magnitude of an output signal of an IFFT unit 126 of a signal having no circular shift.

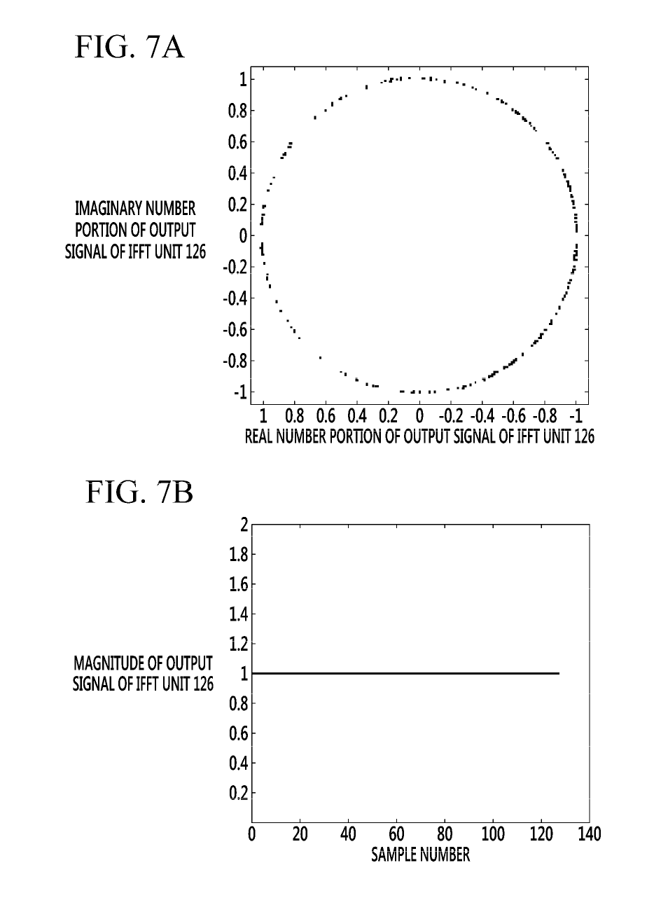

Further, FIG. 7A is a graph illustrating an output signal of an IFFT unit 126 of a signal that is shifted to a 20th circular shift in a right direction, and FIG. 7B is a graph illustrating a magnitude of an output signal of an IFFT unit 126 of a signal that is shifted to a 20th circular shift in a right direction.

As shown in FIGS. 6B and 7B, a magnitude of the output signal of the IFFT unit 126 becomes 1 regardless of a circular shift value. That is, in the output signal of the IFFT unit 126, a PAPR becomes 0 dB regardless of a circular shift value.

Referring again to FIG. 2, the PSC 127 converts a parallel signal of a time domain that is output from the IFFT unit 126 to a serial signal (S222), and outputs the converted serial signal to the signal transmitting unit 130.

The signal transmitting unit 130 converts a signal that is output from the PSC 127 to a wireless frequency signal and transmits the wireless frequency signal (S224).

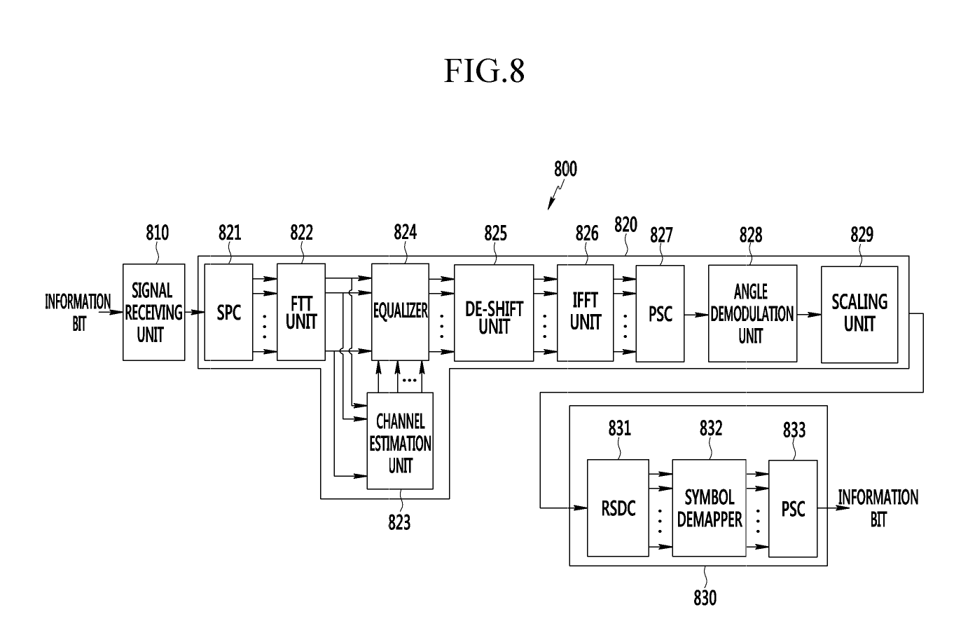

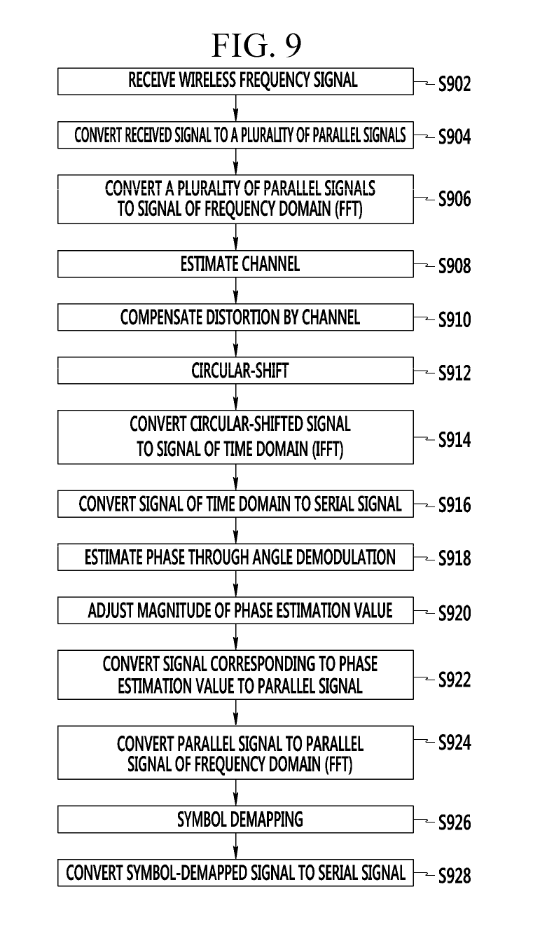

FIG. 8 is a diagram illustrating a CE-OFDM data receiving apparatus according to an exemplary embodiment of the present invention, and FIG. 9 is a flowchart illustrating a method of receiving data of a CE-OFDM data receiving apparatus according to an exemplary embodiment of the present invention.

Referring to FIG. 8, a CE-OFDM data receiving apparatus 800 includes a signal receiving unit 810, a PAPR controller 820, and an OFDM demodulation unit 830.

The signal receiving unit 810, the PAPR controller 820, and the OFDM demodulation unit 830 perform a reverse function of the signal transmitting unit 130, the PAPR controller 120, and the OFDM modulation unit 110, respectively, of the CE-OFDM data transmitting apparatus 100.

Such a PAPR controller 820 includes an SPC 821, an FFT unit 822, a channel estimation unit 823, an equalizer 824, a de-shift unit 825, an IFFT unit 826, a PSC 827, an angle demodulation unit 828, and a scaling unit 829. Further, the OFDM demodulation unit 830 includes a real signal de-converter (RSDC) 831, a symbol demapper 832, and a PSC 833.

Referring to FIG. 9, when a wireless frequency signal is received (S902), the signal receiving unit 810 processes the received signal and outputs the processed signal to the SPC 821 of the PAPR controller 820.

The SPC 821 converts signals that are received in series to a plurality of parallel signals and outputs the converted signal to the FFT unit 822 (S904).

The FFT unit 822 performs FFT of an input plurality of parallel signals and converts a signal of a time domain to a signal of a frequency domain (S906), and outputs the signal of a frequency domain to the channel estimation unit 823 and the equalizer 824.

The channel estimation unit 823 estimates a channel of a corresponding frequency domain using a signal of a frequency domain corresponding to a position of a DC component that is shifted by a circular shift value among signals of a frequency domain that is output from the FFT unit 822 (S908).

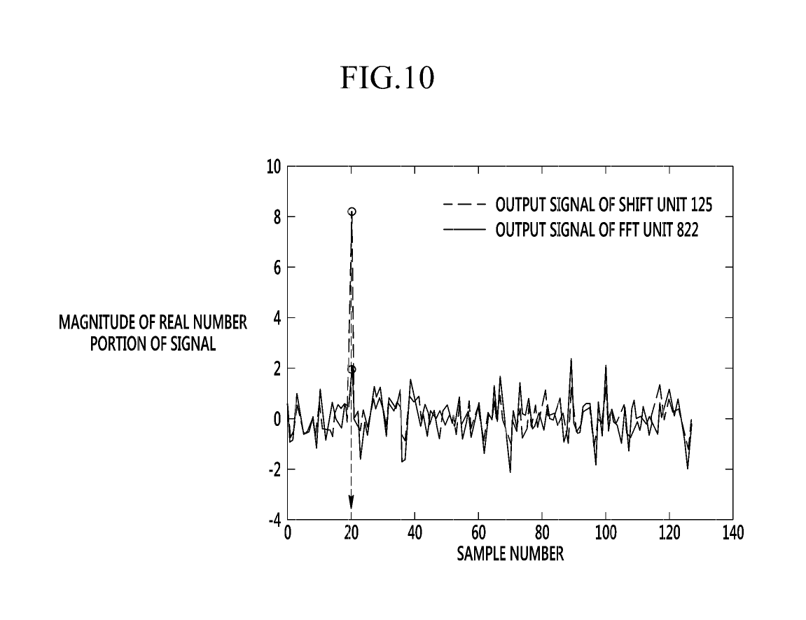

FIG. 10 is a graph illustrating an example of a signal of a frequency domain that is output from the FFT unit 822 that is shown in FIG. 9.

Referring to FIG. 10, when the shift unit 125 of the CE-OFDM data transmitting apparatus 100 shifts a plurality of parallel signals that are output from the FFT unit 124 to a 20th circular shift in a right direction, an output signal of the shift unit 125 has a tendency that is indicated by a dotted line. That is, energy is concentrated at a position of a DC component that is shifted by a circular shift value. When an FFT magnitude is 128 and an OFDM modulation method is 16 QAM, a magnitude of a DC component statistically has a value of about 10.

When an output signal of the shift unit 125 is processed and transmitted, as described above, and it is assumed that a signal that is received in the CE-OFDM data receiving apparatus 800 is the same as a solid line, the channel estimation unit 823 calculates a magnitude of a signal of a frequency domain corresponding to a position (subcarrier position corresponding to a 20th sample number) of a DC component that is shifted by a circular shift value and estimates a channel from the calculated magnitude and a magnitude of a DC component. Thereby, channel information about one subcarrier per OFDM symbol can be obtained.

The channel estimation unit 823 updates a channel estimation value at a position of a corresponding subcarrier to a calculated channel estimation value.

Referring again to FIG. 9, the equalizer 824 compensates distortion by a channel of a signal of a frequency domain that is output from the FFT unit 822 using a channel that is estimated by the channel estimation unit 823 (S910), and outputs the signal to the de-shift unit 825. For example, when a channel estimation value that is output from the channel estimation unit 823 is h_{f1}, h_{f2}, . . . , h_{fn} and a signal of a frequency domain that is output from the FFT unit 822 is y_{f1}, y_{f2}, . . . , y_{fn}, the equalizer 824 performs an equalization process of Equation 5.

x_{fk}=y_{fk}/h_{fk} (Equation 5)

In this way, as the CE-OFDM data transmitting apparatus 100 shifts a position of a DC component by a circular shift value, the CE-OFDM data receiving apparatus 800 estimates a channel from a circular shift value without additional information such as a pilot and compensates distortion of a signal of a frequency domain that is output from the FFT unit 822 using a channel estimation value.

The de-shift unit 825 circular-shifts a signal that is output from the equalizer 824 in an opposite direction by a circular shift value in the shift unit 125 of the CE-OFDM data transmitting apparatus 100 (S912), and outputs a circular-shifted signal to the IFFT unit 826. For example, when the shift unit 125 of the CE-OFDM data transmitting apparatus 100 shifts an output signal of the FFT unit 124 to a 20th circular shift in a right direction, the de-shift unit 825 shifts an output signal of the equalizer 824 to a 20th circular shift in a left direction.

The IFFT unit 826 performs IFFT of a signal that is output from the de-shift unit 825, converts a signal of a frequency domain to a signal of a time domain (S914), and outputs the signal of a time domain to the PSC 827.

Next, the PSC 827 converts a signal that is output from the IFFT unit 826 from a parallel signal to a serial signal (S916), and outputs the converted signal to the angle demodulation unit 828.

The angle demodulation unit 828 performs angle demodulation of a signal that is output from the PSC 827 and estimates a phase (S918). The angle demodulation unit 828 outputs a phase estimation value to the scaling unit 829. When a signal that is output from the PSC 827 is defined as IS and a phase estimation value is defined as P, the phase estimation value is calculated by performing inverse tangent of a value that divides an imaginary number portion of IS by a real number portion of IS, as in Equation 6.

$$P = arctan [ \frac{imaginary ( IS )}{real ( IS )} ] \qquad ( Equation 6 )$$

The scaling unit 829 divides a phase estimation value that is calculated by the angle demodulation unit 828 by an angle demodulation index m, and adjusts a magnitude of the phase estimation value (S920) and outputs the phase estimation value to the RSDC 831.

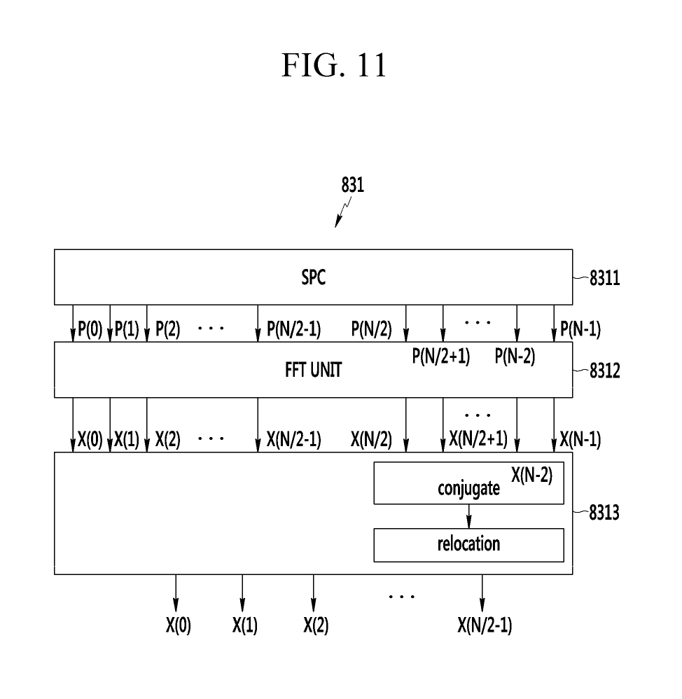

FIG. 11 is a diagram illustrating an RSDC that is shown in FIG. 8.

Referring to FIG. 11, the RSDC 831 includes an SPC 8311, an FFT unit 8312, and an output unit 8313.

Referring again to FIG. 9, in order to perform FFT of a signal corresponding to a phase estimation value, the SPC 8311 converts a phase estimation value from a serial signal to a parallel signal and outputs the converted value to the FFT unit 8312 (S922).

When a parallel signal that is converted by the SPC 8311 is input to input signals [P(0), P(1), . . . , P(N−1)] of the FFT unit 8312, the FFT unit 8312 performs FFT of the input signals [P(0), P(1), . . . , P(N−1)]. Thereafter, the input signals [P(0), P(1), . . . , P(N−1)] are converted from a signal of a time domain to signals [X(0), X(1), . . . , X(N−1)] of a frequency domain (S924).

The output unit 8313 outputs signals [X(0), X(1), . . . , X(N/2−1)] of a frequency domain among the signals [X(0), X(1), . . . , X(N−1)] of a frequency domain to the symbol demapper 832. In this case, the output unit 8313 outputs data symbols [X(0), X(1), . . . , X(N/2−1)] to the symbol demapper 832. Alternatively, the output unit 8313 conjugates data symbols [X(N/2), . . . , X(N−1)] of a frequency domain, relocates the data symbols at a position of X(N−k), and outputs the data symbols to the symbol demapper 832. Here, k is N/2, N/2+1, . . . , N−1. For example, in the symbol [X(N−1)] of a frequency domain after performing FFT, the output unit 8313 conjugates the symbol [X(N−1)] of a frequency domain and relocates the symbol [X(N−1)] at a position of X(1).

Next, the symbol demapper 832 performs symbol-demapping of a signal that is output from the output unit 8313 through digital demodulation such as BPSK, QAM, 16-QAM, and 64-QAM, and outputs the signal to the PSC 833 (S926).

The PSC 833 converts the signal that is output from the symbol demapper 832 from a parallel signal to a serial signal (S928), thereby restoring information bits.

According to the exemplary embodiment of the present invention, while satisfying OFDM characteristics strong on multiple path fading, a PAPR can be 0 dB.

Further, by shifting a DC component in which energy is concentrated in a frequency domain, the DC component can be used for estimating a frequency channel and for adjusting time synchronization in a time domain. By using the DC component, it is unnecessary to periodically transmit an additional information signal for estimating a channel at a specific subcarrier position like a pilot, and thus a data transmission capacity can be increased.

An exemplary embodiment of the present invention may not only be embodied through the above-described apparatus and/or method but may also be embodied through a program that executes a function corresponding to a configuration of the exemplary embodiment of the present invention or through a recording medium on which the program is recorded, and can be easily embodied by a person of ordinary skill in the art from a description of the foregoing exemplary embodiment.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An apparatus that transmits data, comprising:
an orthogonal frequency-division multiplexing (OFDM) modulation unit that generates a plurality of modulation data symbols by performing symbol mapping of input data and that converts the plurality of modulation data symbols from a signal of a frequency domain to a real number signal of a time domain;
a peak-to-average power ratio (PAPR) controller that angle-modulates the real number signal of a time domain and that circular-shifts the angle-modulated signal from a signal of a frequency domain; and
a signal transmitting unit that transmits the circular-shifted signal.

2. The data transmitting apparatus of claim 1, wherein the OFDM modulation unit comprises:
an input signal processor that generates a plurality of input signals using the plurality of modulation data symbols; and
an inverse fast Fourier transform (IFFT) unit that generates the real number signal by performing IFFT of the plurality of input signals,
wherein the plurality of input signals comprise the plurality of modulation data symbols and a plurality of conjugation symbols that are generated by conjugating the plurality of modulation data symbols.

3. The data transmitting apparatus of claim 2, wherein the number of the plurality of modulation data symbols is N/2, when a magnitude of the IFFT is N,
the input signal processor corresponds N/2 modulation data symbols to positions from 0 to an (N/2−1)th input signal, corresponds a plurality of conjugation symbols of N/2 to positions from N/2 to an (N−1)th input signal, and positions a conjugation symbol of an (N/2−k)th input signal at positions of input signals from N/2nd to N−1, and
the N is a positive number, and k is a value from N/2 to N−1.

4. The data transmitting apparatus of claim 1, wherein the PAPR controller comprises:
a fast Fourier transform (FFT) unit that converts the angle-modulated signal from a signal of a time domain to a signal of a frequency domain;
a shift unit that shifts the signal of a frequency domain by a predetermined circular shift value; and
an IFFT unit that converts the circular-shifted signal from a signal of a frequency domain to a signal of a time domain and that outputs the converted signal to the signal transmitting unit.

5. The data transmitting apparatus of claim 1, wherein the PAPR controller comprises a scaling unit that adjusts a magnitude of the real number signal by multiplying an angle modulation index by the real number signal of a time domain.

6. An apparatus that receives data, comprising:
a signal receiving unit that receives a signal from a data transmitting apparatus;
a PAPR controller that converts a received signal from a time domain to a signal of a frequency domain and that circular-shifts the signal of a frequency domain in an opposite direction by a circular shift value of a data transmitting apparatus, and that calculates a phase estimation value by angle demodulation; and
an OFDM demodulation unit that converts the phase estimation value from a time domain to a signal of a frequency domain and that restores data by symbol demapping.

7. The data receiving apparatus of claim 6, wherein the PAPR controller comprises:
an FFT unit that converts the receiving signal from a time domain to a signal of a frequency domain;
a channel estimation unit that estimates a channel from a magnitude of a DC component that is shifted by a circular shift value in the data transmitting apparatus among signals of a frequency domain; and
an equalizer that compensates the signal of a frequency domain using the estimated channel.

8. The data receiving apparatus of claim 7, wherein the PAPR controller further comprises a scaling unit that adjusts a magnitude of the phase estimation value by dividing the phase estimation value by an angle modulation index,
wherein the angle modulation index is used for adjusting a magnitude of a signal in the data transmitting apparatus.

9. The data receiving apparatus of claim 6, wherein the PAPR controller comprises:
an IFFT unit that converts a circular-shifted signal of a frequency domain to a signal of a time domain; and
an angle demodulation unit that calculates a phase estimation value by performing inverse tangent of a value that divides an imaginary number value by a real number signal in the signal of a time domain.

10. A method of transmitting data in a data transmitting apparatus, the method comprising:
generating a plurality of modulation data symbols by performing symbol mapping of input data;
converting the plurality of modulation data symbols from a frequency domain to a real number signal of a time domain;
angle-modulating the real number signal of a time domain;
circular-shifting the angle modulated-signal from a signal of a frequency domain; and
transmitting the circular-shifted signal.

11. The method of claim 10, wherein the circular-shifting of the angle modulated-signal comprises:
converting the angle modulated-signal from a signal of a time domain to the signal of a frequency domain; and
shifting an entire signal of a frequency domain by a predetermined circular shift value.

12. The method of claim 10, wherein the transmitting of the circular-shifted signal comprises:
converting the circular-shifted signal from the frequency domain to a signal of a time domain; and
converting the signal of a time domain to a wireless frequency signal.

13. The method of claim 10, wherein the converting of the plurality of modulation data symbols comprises:
generating a plurality of input signals using the plurality of modulation data symbols; and
generating the real number signal by performing IFFT of the plurality of input signals,
wherein the plurality of input signals comprise the plurality of modulation data symbols and a plurality of conjugation symbols that are generated by conjugating the plurality of modulation data symbols.

14. The method of claim 13, wherein the number of the plurality of modulation data symbols is N/2, when a magnitude of the IFFT is N,
N/2 modulation data symbols are used for input signals from 0 to an (N/2−1)th input signal, and a conjugation symbol of an (N/2−k)th input signal is used for input signals from N/2nd to (N−1)th, and
the N is a positive number, and k is a value from N/2 to N−1.

15. A method of receiving data in a data receiving apparatus, the method comprising:
converting a received signal from a time domain to a signal of a frequency domain;
estimating a channel from a magnitude of a DC component that is shifted by a circular shift value in a data transmitting apparatus among the signal of a frequency domain; and
compensating distortion of the signal of a frequency domain using the estimated channel.

16. The method of claim 15, further comprising:
calculating a phase estimation value by circular-shifting and angle-demodulating the signal of a frequency domain in which distortion is compensated in an opposite direction by the circular shift value; and
restoring the data by symbol-demapping the phase estimation value in a signal of a frequency domain.

17. The method of claim 16, wherein the calculating of a phase estimation value comprises:
converting the circular-shifted signal from a frequency domain to a signal of a time domain; and
angle-demodulating the signal of a time domain.

18. The method of claim 16, wherein the restoring of the data comprises:
converting the phase estimation value from a serial signal to a parallel signal;
performing FFT of the parallel signal and a plurality of conjugation signals that are generated by conjugating the parallel signal; and
selecting a portion of the fast Fourier-transformed data symbols as the plurality of data symbols.
